(19) United States
(12) Patent Application Publication
(10) Pub. No.: US 2011/0057236 A1
(43) Pub. Date: Mar. 10, 2011

(54) Inertial sensor having a field effect transistor

(76) Inventor: Ando Feyh, Tamm (DE)

(21) Appl. No.: 12/804,981

(22) Filed: Aug. 2, 2010

(30) Foreign Application Priority Data
Sep. 4, 2009 (DE) 10 2009 029 217.9

(51) Int. Cl. H01L 29/84; H01L 21/64

(52) U.S. Cl. 257/254; 438/53; 257/E29.324; 257/E21.4

(57) ABSTRACT

An inertial sensor, having a field effect transistor which includes a gate electrode (9), a source electrode (3a′,3a″,3a′″), a drain electrode (3b′,3b″,3b′″) and a channel area (4) situated between the source electrode (3a′,3a″,3a′″) and the drain electrode (3b′,3b″,3b′″) and whose gate electrode (9) is situated at a distance above the channel area (4). The gate electrode (9) is designed and situated to be stationary and the channel area (4) is designed and situated to be movable. Furthermore, the present invention also relates to a method for manufacturing a motion sensor of this type.

### BACKGROUND OF THE INVENTION

1. Field of the Invention

The present invention relates to an inertial sensor having a field effect transistor and a method for manufacturing a motion sensor of this type.

2. Description of Related Art

Published German patent document DE 102 36 773 A1 describes an acceleration sensor having a field effect transistor which has a two-layer electrode structure including a first movable detection electrode and a second movable detection electrode, whose deflection directions have the same orientation when subjected to acceleration.

### SUMMARY OF THE INVENTION

The subject of the present invention is an inertial sensor having a field effect transistor (FET) which includes a gate electrode, a source electrode, a drain electrode and a channel area situated between the source electrode and the drain electrode, and whose gate electrode is situated at a distance above the channel area. According to the present invention, the gate electrode is designed and situated to be stationary and the channel area is designed and situated to be movable. The term “above” describes the positioning of the gate electrode with regard to the channel area and not the orientation of the gate electrode and the channel area with regard to gravitation.

In contrast to conventional inertial sensors, which operate on the basis of a moving gate principle, an inertial sensor according to the present invention detects an acting acceleration on the basis of a moving channel principle. In an acting acceleration, the distance between the gate electrode and the channel area is varied, and the current flow through the transistor is modulated thereby, which may be directly read out using electrical means.

An inertial sensor according to the present invention may advantageously have a high sensitivity and a simple evaluation circuit. At the same time, the channel area may advantageously be used as a seismic ground. Moreover, in an inertial sensor according to the present invention, a C/U conversion may advantageously be dispensed with.-Furthermore, an inertial sensor according to the present invention may advantageously be highly miniaturized. The manufacture of an inertial sensor according to the present invention may also be advantageously fully integrated into an ASIC process. In addition, an inertial sensor according to the present invention may advantageously have a cap formed with the aid of a thin-film process. Furthermore, through-contacts are advantageously not required to manufacture an inertial sensor according to the present invention.

### BRIEF DESCRIPTION OF THE DRAWINGS

Further advantages and advantageous embodiments of the subjects of the present invention are illustrated by the drawings and explained in the following description. It should be noted that the drawings are only descriptive in nature and are not intended to limit the present invention in any way.

FIG. 1 shows a cross section of a structure formed in method step a).

FIG. 2 shows a cross section of the structure illustrated in FIG. 1 after completing method step b).

FIG. 3 shows a top view of the structure illustrated in FIG. 1 after completing method step b).

FIG. 4 shows a cross section of the structure illustrated in FIG. 1 after completing method steps c) through e).

FIG. 5 shows a cross section of the structure illustrated in FIG. 1 after completing method steps f) through h).

### DETAILED DESCRIPTION OF THE INVENTION

According to a specific embodiment of the present invention, the inertial sensor is an acceleration sensor, in particular a linear acceleration sensor, or a yaw-rate sensor.

Distance (d) between the gate electrode and the channel area may be, for example from ≧1 nm to ≦10 μm, for example from ≧5 nm to ≦5 μm. In particular, an inertial sensor according to the present invention may be designed as a monolithically integrated sensor.

According to a further specific embodiment of the present invention, the channel area is situated within a cavity which is at least partially closed by the gate electrode. In addition to the gate electrode, the cavity may also be closed by a passivation layer and/or contacts for contacting the gate electrode, drain electrode and/or source electrode. In this way, components which may already be present for other purposes are used simultaneously for multiple functions, which makes it possible to advantageously minimize the entire space required by an inertial sensor according to the present invention.

According to a further specific embodiment of the present invention, the channel area is elastically suspended, the source electrode forming a first part of the suspension and the drain electrode forming a second part of the suspension. In this case, components are also used for multiple purposes, which makes it possible to advantageously further minimize the entire space requirement.

According to a further specific embodiment of the present invention, the channel area is movable in the direction of the gate electrode (z direction) and/or parallel to the gate electrode (x,y direction). In a channel area which is movable in the direction of the gate electrode, the capacitance between the channel area and the gate electrode may vary as the distance (d) between the gate electrode and the channel area changes. In a channel area which is movable parallel to the gate electrode, the capacitance between the channel area and the gate electrode may vary as the size of the overlapping surface between the gate electrode and the channel area changes. In both cases, the variation is detectable by electrical means.

According to a further specific embodiment of the present invention, the channel area is provided with a passivating thermal oxide layer. For example, the passivating thermal oxide layer may be a layer made of silicon oxide (SiO₂), silicon nitride (SiN, Si₃N₄) and/or silicon carbide (SiC). A passivating thermal oxide layer may advantageously affect the electrical properties of the channel area.

In particular, an inertial sensor according to the present invention may be an inertial sensor which is manufactured with the aid of a method according to the present invention, which is explained below.

With regard to further features and advantages of an inertial sensor according to the present invention, reference is hereby explicitly made to the explanations in connection with the method according to the present invention for manufacturing inertial sensors.

A further subject of the present invention is a method for manufacturing a motion sensor, in particular an inertial sensor according to the present invention explained above, which includes the following method steps:
a) forming a first cavity area, an at least two-part suspension and a diaphragm which is movably suspended between the parts of the suspension above the first cavity area on and/or in a carrier substrate, in particular a substrate wafer;
b) implanting electron acceptor atoms into the material of the suspension and implanting electron donator atoms into the material of the diaphragm or implanting electron donator atoms into the material of the suspension and implanting electron acceptor atoms into the material of the diaphragm;
c) depositing and structuring a sacrificial layer;
d) depositing and structuring a gate electrode;
e) depositing and structuring a passivation layer having access openings for etching the sacrificial layer;
f) etching the sacrificial layer;
g) closing the access openings; and
h) forming electrical contacts for contacting the gate electrode, source electrode and drain electrode.

Due to the suspension, the diaphragm or the channel area is, in particular, mechanically decoupled from the carrier substrate in such a way that the diaphragm or the channel area becomes movable. The suspension preferably has two parts, each of which includes a first area for electrically contacting the part, a second area designed as an elastic structure and a third area for electrically contacting the diaphragm.

Method step a) may be carried out, for example, via a process which is also used, for example, in manufacturing micromechanical pressure sensors or via an SOI wafer process if an SOI wafer is used as the carrier substrate. If an SOI wafer having an oxide layer between a device layer and a carrier layer is used, the oxide layer may be locally etched to form a first cavity area, a suspension and a movably suspended diaphragm.

Due to method step b), a first part of the suspension may act as the source electrode, a second part of the suspension may act as the drain electrode and the diaphragm situated between the first and second parts of the suspension may act as the channel area of the field effect transistor. The implantations may each be executed in method step b) in such a way that a p- or n-channel field effect transistor is generated. Electron acceptor atoms are preferably implanted into the material of the suspension and electron donator atoms are implanted into the material of the diaphragm. In other words, the source electrode and the drain electrode are preferably p-doped, and the channel area is preferably n-doped.

According to a further specific embodiment of the present invention, the sacrificial layer is deposited and structured on the diaphragm and areas of the suspension in method step c).

According to a further specific embodiment of the present invention, the gate electrode is deposited and structured on an area of the sacrificial layer in method step d). Method step d) may be carried out before or after or, if necessary, at the same time as method step e).

According to a further specific embodiment of the present invention, method step e) is carried out before method step d), the passivation layer being removed at the position where gate electrode (9) will be deposited in subsequent method step d). This makes it possible to advantageously increase flexibility in processing the available materials.

According to a further specific embodiment of the present invention, the passivation layer is deposited and structured in areas of the sacrificial layer and the carrier substrate in method step e), for example in areas of the sacrificial layer, the suspension and the carrier substrate.

In method step f), the sacrificial layer may be etched, in particular forming a second cavity area above the diaphragm and above areas of the suspension. The access openings may be closed in method step g), for example using a thin film process. In method step h), the electrical contacts for contacting the gate electrode, source electrode and drain electrode may be formed by metal deposition, for example by forming contact openings and subsequently depositing metal in the contact openings. If necessary, method steps g) and h) may be combined by situating and forming the access openings for etching the sacrificial layer in such a way that, after etching the sacrificial layer, the access openings are also used as contact openings for forming electrical contacts for contacting the drain electrode and/or source electrode, and the access openings are closed by forming electrical contacts for contacting the drain electrode and/or source electrode.

According to a further specific embodiment of the present invention, the diaphragm and suspension are made of monocrystalline, doped silicon.

According to a further specific embodiment of the present invention, the sacrificial layer is made of silicon oxide (Si oxide) and/or silicon germanium (SiGe). The thickness of the sacrificial layer may determine the sensitivity of the field effect transistor by capacitive coupling. In particular, the sacrificial layer may have a layer thickness (d) from ≧1 nm to ≦10 μm, for example from ≧5 nm to ≦5 μm.

According to a further specific embodiment of the present invention, the gate electrode is made of a metal and/or polycrystalline silicon (polysilicon).

According to a further specific embodiment of the present invention, the passivation layer is made of polycrystalline silicon (polysilicon), silicon oxide (Si oxide) and/or silicon nitride (Si nitride).

According to a further specific embodiment of the present invention, the gate electrode, the passivation layer and/or the contacts for contacting the gate electrode, source electrode and drain electrode simultaneously act as a thin film cap.

With regard to further features and advantages of methods according to the present invention for manufacturing inertial sensors, reference is hereby explicitly made to the explanations in connection with inertial sensors according to the present invention.

A further subject of the present invention is an inertial sensor which is manufactured using a method according to the present invention.

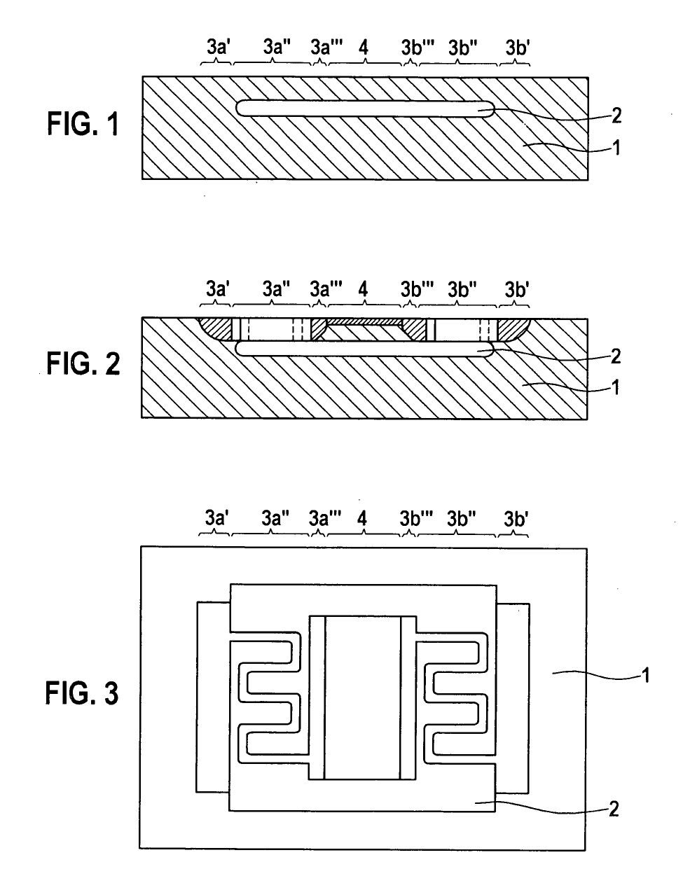

FIG. 1 shows a first cavity area 2 formed in a carrier substrate 1, a two part suspension 3a′, 3a″, 3a′″, 3b′, 3b″, 3b′″ formed on carrier substrate 1 and a diaphragm 4 which is movably suspended between the parts of suspension 3a′, 3a″, 3a′″, 3b′, 3b″, 3b′″ above first cavity area 2. FIG. 1 and FIGS. 2 through 5 explained below further show that the suspension has two parts, each of which includes a first area 3a′, 3b′ for electrical contacting of that particular part, a second area 3a″, 3b″ designed as an elastic structure and a third area 3a′″, 3b′″ for electrical contacting of diaphragm 4.

FIG. 2 shows a cross section of the structure illustrated in FIG. 1 after implanting electron acceptor atoms into the material of suspension 3a′, 3a″, 3a′″, 3b′, 3b″, 3b′″ and after implanting electron donator atoms into the material of diaphragm 4.

FIG. 3 shows a top view of the structure from FIG. 2, including elastic structures 3a″, 3b″ sketched by way of example.

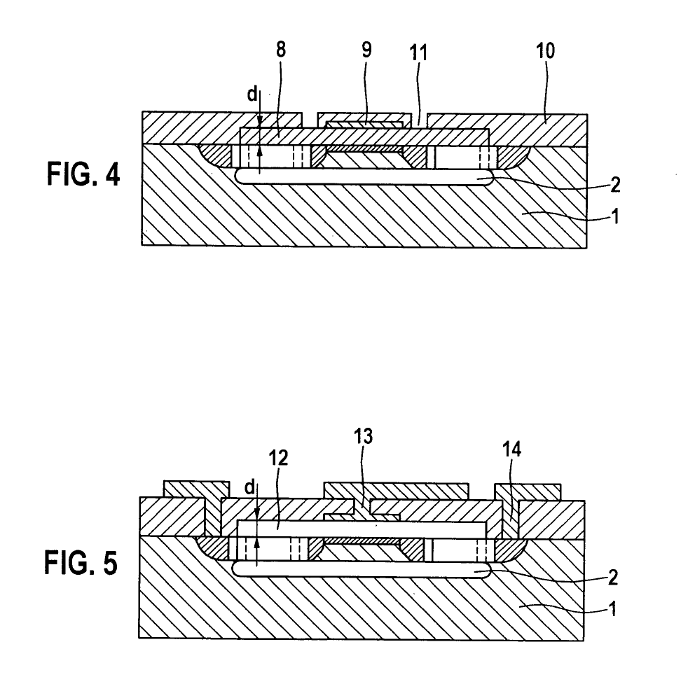

FIG. 4 shows that, in method step c), a sacrificial layer 8 was deposited and structured on diaphragm 4 and in second area 3a″, 3b″ and third area 3a′″, 3b′″ of the suspension parts. FIG. 4 also shows that, in method step d), a gate electrode 9 was deposited and structured in an area of sacrificial layer 8. FIG. 4 further shows that, in method step e), a passivation layer 10 having access openings 11 for etching sacrificial layer 8 was deposited and structured in areas of sacrificial layer 8 and of carrier substrate 1.

FIG. 5 shows a finished inertial sensor. FIG. 5 illustrates the fact that sacrificial layer 8 was etched away in method step f), forming a second cavity area 12 above diaphragm 4 and above second area 3a″, 3b″ and third area 3a′″, 3b′″ of the suspension parts. FIG. 5 further shows that access openings 11 for etching sacrificial layer 8 were closed in method step g). Furthermore, FIG. 5 shows that electrical contacts 13, 14 for contacting gate electrode 9, source electrode 3a′, 3a″, 3a′″ and drain electrode 3b′, 3b″, 3b′″ were formed in method step h) by forming contact openings and subsequently depositing metal in the contact openings.

What is claimed is:

1. An inertial sensor having a field effect transistor, comprising:
a gate electrode,
a source electrode,
a drain electrode and
a channel area situated between the source electrode and the drain electrode, the gate electrode being situated at a distance above the channel area,
wherein the gate electrode is designed and situated to be stationary and the channel area is designed and situated to be movable.

2. The inertial sensor as recited in claim 1, wherein the channel area is situated within a cavity which is at least partially closed by the gate electrode.

3. The inertial sensor as recited in claim 1, wherein the channel area is suspended in an elastic manner, the source electrode forming a first part of the suspension and the drain electrode forming a second part of the suspension.

4. The inertial sensor as recited in claim 2, wherein the channel area is suspended in an elastic manner, the source electrode forming a first part of the suspension and the drain electrode forming a second part of the suspension.

5. The inertial sensor as recited in claim 1, wherein the channel area is movable in the direction of the gate electrode or the channel area is movable parallel to the gate electrode.

6. The inertial sensor as recited in claim 2, wherein the channel area is movable in the direction of the gate electrode or the channel area is movable parallel to the gate electrode.

7. The inertial sensor as recited in claim 3, wherein the channel area is movable in the direction of the gate electrode or the channel area is movable parallel to the gate electrode.

8. The inertial sensor as recited in claim 1, wherein the channel area is provided with a passivating thermal oxide layer.

9. The inertial sensor as recited in claim 2, wherein the channel area is provided with a passivating thermal oxide layer.

10. The inertial sensor as recited in claim 3, wherein the channel area is provided with a passivating thermal oxide layer.

11. The inertial sensor as recited in claim 5, wherein the channel area is provided with a passivating thermal oxide layer.

12. The inertial sensor as recited in claim 1, wherein the inertial sensor is an acceleration sensor or a yaw-rate sensor.

13. A method for manufacturing an inertial sensor, comprising:
a) forming a first cavity area, an at least two-part suspension and a diaphragm which is movably suspended between parts of the suspension above the first cavity area on or in a carrier substrate;
b) implanting electron acceptor atoms into material of the suspension and implanting electron donator atoms into material of the diaphragm or implanting electron donator atoms into the material of the suspension and implanting electron acceptor atoms into the material of the diaphragm;
c) depositing and structuring a sacrificial layer;
d) depositing and structuring a gate electrode;
e) depositing and structuring a passivation layer having access openings for etching the sacrificial layer;
f) etching the sacrificial layer;
g) closing the access openings, and
h) forming electrical contacts for contacting the gate electrode, source electrode and drain electrode.

14. The method as recited in claim 13, wherein at least one of the following occurs:
c) the sacrificial layer is deposited and structured on the diaphragm and in areas of the suspension,
d) the gate electrode is deposited and structured in an area of the sacrificial layer, and
e) the passivation layer is deposited and structured in areas of the sacrificial layer and the carrier substrate.

15. The method as recited in claim 13, wherein at least one of the following applies:
the diaphragm and the suspension are made of monocrystalline, doped silicon,
the sacrificial layer is made of at least one of silicon oxide and silicon germanium,
the gate electrode is made of a metal or polycrystalline silicon, and
the passivation layer is made of at least one of polycrystalline silicon, silicon oxide and silicon nitride.

16. The method as recited in claim 14, wherein at least one of the following applies:
the diaphragm and the suspension are made of monocrystalline, doped silicon,
the sacrificial layer is made of at least one of silicon oxide and silicon germanium,
the gate electrode is made of a metal or polycrystalline silicon, and
the passivation layer is made of at least one of polycrystalline silicon, silicon oxide and silicon nitride.

17. The method as recited in claim 13, wherein at least one the gate electrode, the passivation layer and the contacts for contacting the gate electrode, source electrode and drain electrode act as a thin film cap.

18. The method as recited in claim 14, wherein at least one the gate electrode, the passivation layer and the contacts for contacting the gate electrode, source electrode and drain electrode act as a thin film cap.

19. The method as recited in claim 13, wherein step e) is carried out before step d), the passivation layer being removed at a position where the gate electrode will be deposited in subsequent step d).

20. The method as recited in claim 14, wherein step e) is carried out before step d), the passivation layer being removed at a position where the gate electrode will be deposited in subsequent step d).
